(19) United States
(12) Patent Application Publication
(10) Pub. No.: US 2009/0256792 A1
(43) Pub. Date: Oct. 15, 2009

(54) Display Device

(75) Inventors: Katsumi MATSUMOTO, Mobara (JP); Kozo Yasuda, Mobara (JP); Naohisa Ando, Mobara (JP); Toshio Miyazawa, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/420,991

(22) Filed: Apr. 9, 2009

(30) Foreign Application Priority Data
Apr. 11, 2008 (JP) 2008-103403

(51) Int. Cl. G09G 3/36; H03L 5/00

(52) U.S. Cl. 345/94; 327/333

(57) ABSTRACT

An object of the present invention is to increase the reliability in the level shift operation in a display device provided with a level shift circuit. The display device according to the present invention is characterized in that the above described level shift circuit comprises: a first thin film transistor having a semiconductor layer formed of a polysilicon layer; a waveform rectifying circuit connected to a second electrode of the above described first thin film transistor; and a constant current source and a switching element connected between the second electrode of the above described first thin film transistor and a reference power source, wherein a bias voltage is inputted into a control electrode of the above described first thin film transistor and an input signal is inputted into a first electrode of the above described first thin film transistor.

The present application claims priority over Japanese Application JP 2008-103403 filed on Apr. 11, 2008, the contents of which are hereby incorporated into this application by reference.

### BACKGROUND OF THE INVENTION

(1) Field of the Invention

The present invention relates to a display device and, in particular, to an active matrix type display device where a drive circuit (peripheral circuit) is formed in the periphery of a display region on the same substrate as active elements.

(2) Related Art Statement

As conventional liquid crystal display devices, active matrix type liquid crystal display devices where each pixel has an active element and the active elements are operated through switching are known.

In one active matrix type liquid crystal display device that is publicly known, thin film transistors having a semiconductor layer formed of a polysilicon (polycrystal silicon) layer (hereinafter referred to as polysilicon thin film transistor) are used as active elements. In this type of liquid crystal display device, the mobility of polysilicon is higher than that of amorphous silicon, and therefore, it is possible to fabricate a drive circuit for driving the active elements on the same substrate in the same process for fabricating active elements.

Therefore, in recent years, a so-called system in liquid crystal panel has also been mass produced as a product where a circuit for an external driver is simultaneously fabricated on the same glass substrate as the pixels using polysilicon thin film transistors.

In the case of a system in liquid crystal panel, data and control signals having a low amplitude voltage from a microcomputer (3.3 V or lower) are inputted directly into a drive circuit formed of polysilicon thin film transistors, and therefore, the drive circuit needs a level shift circuit for converting the amplitude voltage of the data and control signals to such an amplitude voltage that the polysilicon thin film transistors can operate.

In addition, a level shift circuit having a function of cutting off signals coming from the outside in a state where there is no access from a microcomputer in a system in liquid crystal panel where an SRAM (static random access memory) is provided within the pixel array so that it is unnecessary to rewrite video signals, except in order to update the video, and thus, reduction in the power consumption is possible, is proposed in the below Patent Document 1.

The level shift circuit proposed in Patent Document 1 basically has the configuration of a gate grounded circuit, and is characterized in that the polysilicon thin film transistors for amplifying a voltage also function to cut off signals coming from the outside.

FIG. 5 shows the level shift circuit proposed in Patent Document 1.

In the level shift circuit shown in FIG. 5, the gate 112 of the polysilicon thin film transistor 111 for amplifying a voltage becomes of a high level (hereinafter referred to as H level) at the time of the level shift operation, and the amplitude voltage inputted from the source 113 is amplified and outputted to the drain 114, and the waveform is rectified to the power source amplitude voltage in an inverter 115 in the next stage or any following stage.

Meanwhile, the gate 112 of the polysilicon thin film transistor 111 for amplifying a voltage becomes of a low level (hereinafter referred to as L level) when access is cut off to the outside, and the source 113 on the input side is cut off from the drain 114, and at the same time, a current flowing into an external input terminal from the power source through a resistor 116 and the polysilicon thin film transistor 111 for amplification is also cut off.

[Patent Document 1] Japanese Patent Application 2008-43795

### SUMMARY OF THE INVENTION

### [Problem to Be Solved by the Invention]

However, polysilicon thin film transistors generally have a high threshold value voltage, and the threshold voltage is inconsistent from transistor to transistor, and therefore, in some cases the output voltage fails to rise to the predetermined voltage even if the input signal is of the H level, for example.

Therefore, in the level shift circuit described in the above Patent Document 1, in the case where an enable signal ENA in pulse waveform is inputted into the gate 112 of the polysilicon thin film transistor 111, and the polysilicon thin film transistor 111 carries out a pulse operation, the voltage of the drain 114 fails to rise to the predetermined level, and thus, a problem arises, such that the stability of the level shift operation becomes poor.

The present invention is provided in order to solve the above described problem with the prior art, and an object of the present invention is to increase the reliability in the level shift operation in display devices having a level shift circuit formed of polysilicon thin film transistors.

The above described and other objects, as well as novel characteristics of the present invention, will become clearer from the description in the present specification and the accompanying drawings.

### [Means for Solving Problem]

The gist of typical inventions from among those disclosed in the present specification is described below.
(1) A display device provided with a level shift circuit, wherein the above described level shift circuit has: a first thin film transistor having a semiconductor layer formed of a polysilicon layer; a waveform rectifying circuit connected to a second electrode of the above described first thin film transistor; and a constant current source and a switching element connected between the second electrode of the above described first thin film transistor and a reference power source, and a bias voltage is inputted into a control electrode of the above described first thin film transistor and an input signal is inputted into a first electrode of the above described first thin film transistor, the above described first thin film transistor is an n type thin film transistor, the above described input signal is a signal of which the voltage level changes between a second voltage and a third voltage of which the potential is higher than that of the above described second voltage, the voltage level of the above described reference power source is a first voltage of which the potential is higher than that of the above described third voltage, and the above described level shift circuit converts said input signal of which the voltage level changes between the above described third voltage and the above described second voltage to a signal of which the voltage level changes between the above described first voltage and the above described second voltage.
(2) A display device provided with a level shift circuit, wherein the above described level shift circuit has: a first thin film transistor having a semiconductor layer formed of a polysilicon layer; a waveform rectifying circuit connected to a second electrode of the above described first thin film transistor; and a constant current source and a switching element connected between the second electrode of the above described first thin film transistor and a reference power source, and a bias voltage is inputted into a control electrode of the above described first thin film transistor and an input signal is inputted into a first electrode of the above described first thin film transistor, the above described first thin film transistor is a p type thin film transistor, the above described input signal is a signal of which the voltage level changes between a fourth voltage and a fifth voltage of which the potential is lower than that of the above described fourth voltage, the voltage level of the above described reference power source is a sixth voltage of which the potential is lower than that of the above described fifth voltage, and the above described level shift circuit converts said input signal of which the voltage level changes between the above described fourth voltage and the above described fifth voltage to a signal of which the voltage level changes between the above described fourth voltage and the above described sixth voltage.
(3) The display device according to (1) or (2), wherein the above described constant current source is a resistor.
(4) The display device according to any of (1) to (3), wherein the above described switching element is formed of a second thin film transistor having a semiconductor layer formed of a polysilicon layer.
(5) The display device according to (1) or (2), wherein the above described switching element is formed of a second thin film transistor having a semiconductor layer formed of a polysilicon layer, and the above described second thin film transistor also functions as the above described constant current source when in an on state.

### [Effects of the Invention]

The effects gained by representative inventions from among the inventions disclosed in the present specification are briefly described below.

According to the present invention, it becomes possible to increase the reliability in the level shift operation in display devices provided with a level shift circuit formed of polysilicon thin film transistors.

### BRIEF DESCRIPTION OF THE DRAWINGS

FIG. 1 is a block diagram schematically showing the configuration of the liquid crystal display device according to an embodiment of the present invention;

FIG. 2 is a diagram illustrating the level shift circuit according to the embodiment of the present invention;

FIG. 3 is a circuit diagram showing an example of the level shift circuit according to the embodiment of the present invention;

FIG. 4 is a circuit diagram showing another example of the level shift circuit according to the embodiment of the present invention;

FIG. 5 is a diagram illustrating a level shift circuit according to the prior art; and

FIG. 6 is a circuit diagram showing an example of the level shift circuit according to the prior art.

### DETAILED DESCRIPTION OF THE INVENTION

In the following, an embodiment where the present invention is applied to a liquid crystal display device is described in detail in reference to the drawings.

Here, in all of the drawings for illustrating the embodiment, the same symbols are attached to components having the same functions, and the descriptions thereof are not repeated.

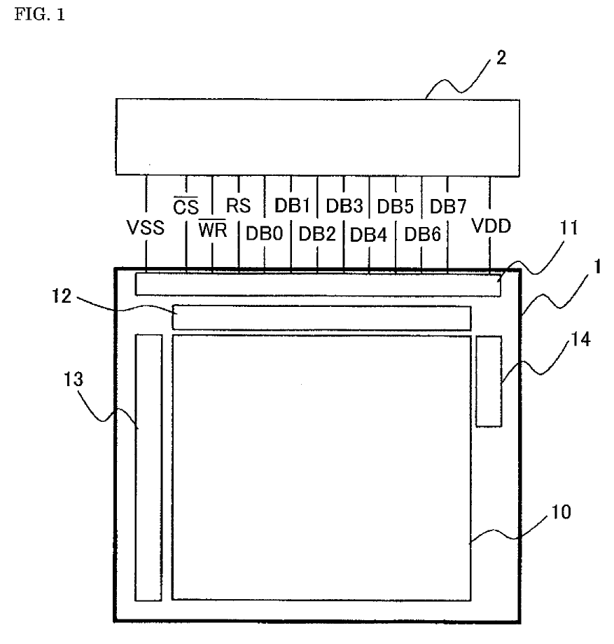

FIG. 1 is a block diagram schematically showing the configuration of the liquid crystal display device according to an embodiment of the present invention. In FIG. 1, 1 is a liquid crystal panel and 2 is a microcomputer.

In general, liquid crystal panels 1 have a pair of substrates and liquid crystal sandwiched between the pair of substrates, and the liquid crystal panel 1 has a pixel array 10 forming a display portion, an X address decoder 12 provided in the periphery of the pixel array 10, a Y address decoder 13, an interface circuit 11 and an oscillation circuit 14.

In the following description, thin film transistors having a semiconductor layer formed of a polysilicon layer are referred to as polysilicon thin film transistors.

The pixel array 10 has a number of pixels arranged in a matrix, and each pixel has a polysilicon thin film transistor (hereinafter referred to as pixel transistor) as an active element. In addition, the X address decoder 12, the Y address decoder 13, the interface circuit 11 and the oscillation circuit 14 arranged in the periphery of the pixel array 10 are formed of polysilicon thin film transistors (hereinafter referred to as transistors for peripheral circuit).

In addition, the transistors for the peripheral circuit and the pixel transistors are fabricated on one of the pair of substrates in the same process.

Here, in the liquid crystal panel 1 in the present embodiment, each pixel within the pixel array 10 has an SRAM (static random access memory) and it is unnecessary to rewrite video signals, except in order to update the video, and thus, it is possible to reduce power consumption.

In the liquid crystal panel 1 in the present embodiment, a signal from the microcomputer 1 is directly inputted into the X address decoder 12 and the Y address decoder 13 through the interface circuit 11. Therefore, the input stage of the interface circuit 11 has a level shift circuit which shifts the level of a low amplitude signal of 3.3 Vp-p or lower outputted from the microcomputer 2 into a signal of 5 Vp-p or higher, which makes it possible for the transistors for the peripheral circuit incorporated in the liquid crystal panel 1 to operate.

Here, in FIG. 1, VSS and VDD are power source voltages, overscored CS, overscored WR and RS are control signals for writing in data, and DB0 to DB7 are data signals.

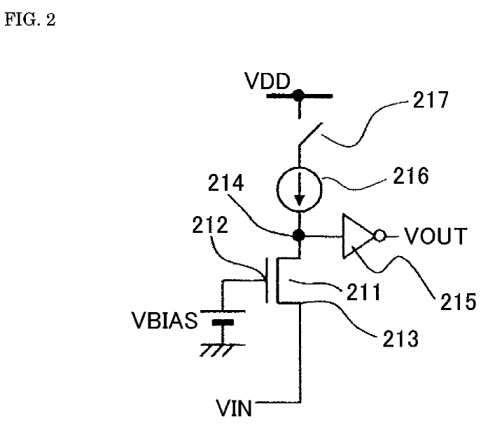

FIG. 2 is a circuit diagram showing the level shift circuit in the embodiment of the present invention.

In the level shift circuit in the present embodiment, a fixed bias voltage (VBIAS) is inputted into the gate 212 of the polysilicon thin film transistor (first thin film transistor in the present invention) 211 for amplifying the voltage, and an input signal (VIN) is inputted the source 213. Here, the polysilicon thin film transistor 211 for amplifying the voltage is an n type polysilicon thin film transistor.

A switching element 217 for cutting off a current path and a constant power source 216 are connected between the drain 214 of the polysilicon thin film transistor 211 for amplifying the voltage and the power source voltage VDD. In addition, an inverter 215 for rectifying the waveform is connected to the drain 214 of the polysilicon thin film transistor 211 for amplifying the voltage.

The switching element 217 for cutting off the current path cuts off the connection between the liquid crystal panel 1 and the outside in a state where there is no access from the microcomputer 2.

The level shift circuit in the present embodiment is different from the level shift circuit shown in FIG. 5 in that the switching element 217 for cutting off the current path which cuts of the current path between the power source VDD and an external terminal is provided on the power source VDD side.

Here, a general p type polysilicon thin film transistor (second thin film transistor in the present invention) is used as the switching element 217, but there are no particular limitations as to the p type polysilicon thin film transistor, and an analog switching element where a p type polysilicon thin film transistor and an n type polysilicon thin film transistor are connected in parallel (so-called transfer gate circuit) may be used, for example.

In addition, the constant current source 216 may be a resistor element, and the switching element 217 for cutting off the current path may have a structure which also functions as a constant current source 216 in an on state.

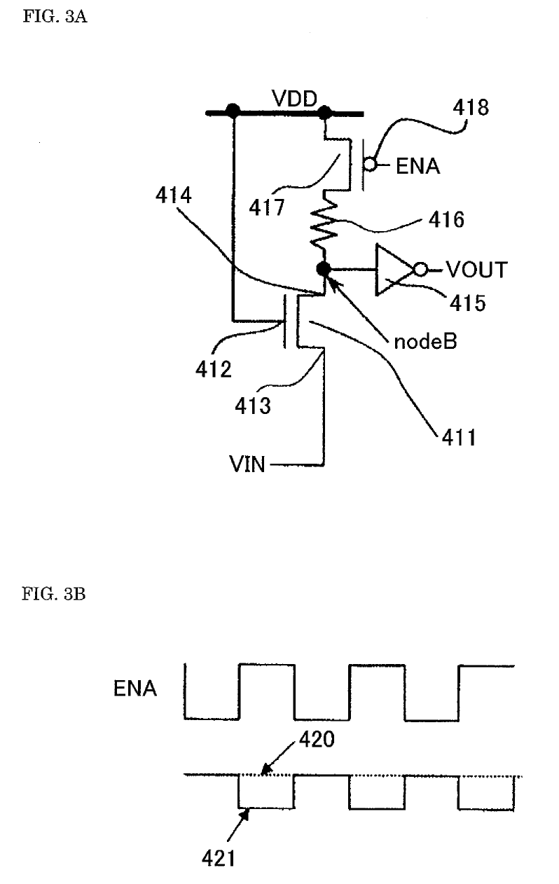

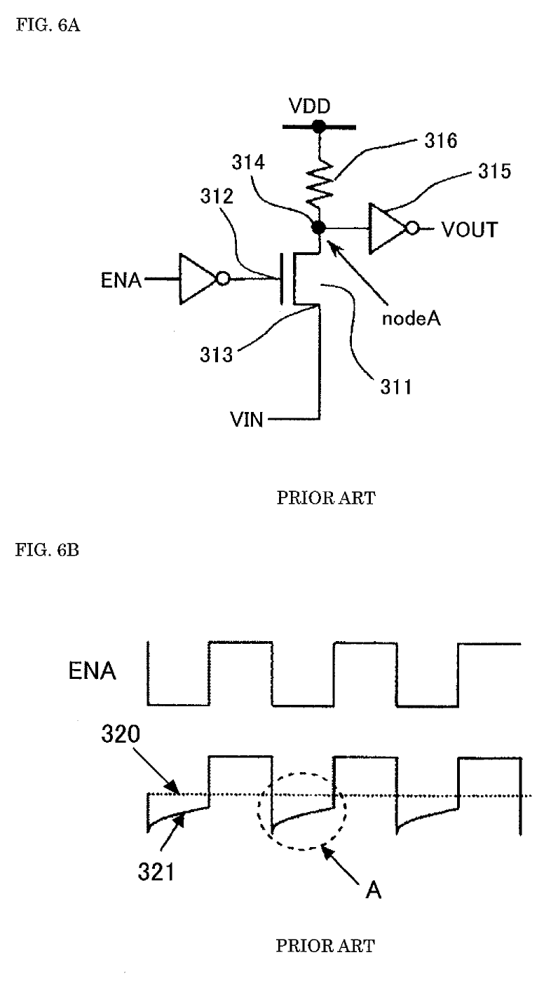

In the following, the effects of the present invention are described in reference to FIGS. 3A, 3B, 6A and 6B. In the level shift circuits shown in FIGS. 3 and 6, an input signal (VIN) of which the low level (hereinafter referred to as L level) is 0 V and the high level (hereinafter referred to as H level) is 3 V is converted to a signal where the L level is 0 V and the H level is 6 V. Therefore, the inverter 415 shown in FIG. 3 and the inverter 315 shown in FIG. 6 are set so that the output becomes of the L level (voltage of 0 V) when the H level (voltage of 3 V) is inputted.

FIG. 6A shows the level shift circuit described in the above Patent Document 1, and FIG. 6B shows the waveform of the amplified voltage at the node A (drain 314 of polysilicon thin film transistor 311 for amplifying voltage) at the time of operation.

When an input voltage at the H level (for example a direct current of 3.3 V) is inputted into the source 313 of the polysilicon thin film transistor 311 for amplifying the voltage, and a direct current voltage is continuously inputted into the gate 312 (that is to say, when the enable signal ENA is fixed at the L level), as in FIG. 6A, the waveform at the node A is 320, as in FIG. 6B. When an enable signal ENA in pulse waveform is inputted into the gate 312 of the polysilicon thin film transistor 311 for amplifying the voltage, and the polysilicon thin film transistor 311 for amplifying the voltage is carrying out a pulse operation, the waveform at the node A is 321, as in FIG. 6B.

Here, when the enable signal ENA is at the L level in the level shift circuit in FIG. 6A, the level shift circuit carries out a level shift operation. In addition, in FIG. 6A, 313 is the source of the polysilicon thin film transistor 311 and 316 is a resistor.

As shown by A in FIG. 6B, it is clear from the characteristics of the polysilicon thin film transistor when carrying out a pulse operation that the voltage at the node A when the polysilicon thin film transistor 311 for amplifying the voltage is turned on (that is to say, during the period when the enable signal ENA in pulse wave form shown in FIG. 6B is at the L level) is lower than the voltage 320 at the node A when a direct current voltage (L level) is continuously inputted into the gate 312 of the polysilicon thin film transistor 311 for amplifying the voltage, and thus, the two voltages are different.

Therefore, in the level shift circuit described in the above Patent Document 1, it is assumed that the output of the inverter 315 becomes of the H level (voltage of 6 V) when the input signal (VIN) is at the H level (voltage of 3 V), for the reasons described above, though the output of the inverter 315 must be at the H level (voltage of 0 V) when the input signal (VIN) is at the H level (voltage of 3 V), and thus, a problem arises, such that the reliability of the level shift circuit becomes poor.

FIG. 3A shows an example of the level shift circuit according to the present embodiment, and FIG. 3B shows the waveform of the amplified voltage at the node B (drain 414 of polysilicon thin film transistor 411 for amplifying voltage) at the time of operation.

In the level shift circuit shown in FIG. 3A, the constant current source 216 shown in FIG. 2 is formed of a resistor 416, and the switching element 217 for cutting off the current path shown in FIG. 2 is formed of a p type polysilicon thin film transistor 417.

In addition, the voltage VDD, which is a bias voltage (VBIAS), is continuously inputted into the gate 412 of the polysilicon thin film transistor 411 for amplifying the voltage, so that the polysilicon thin film transistor 411 for amplifying the voltage is always turned on.

The waveform at the node B when the polysilicon thin film transistor 417 is continuously in an on state (that is to say, the enable signal ENA is fixed at the L level) is 420 in FIG. 3B, while the waveform at the node B when an enable signal ENA in pulse waveform is inputted and the polysilicon thin film transistor 417 is carrying out a pulse operation is 421 in FIG. 3B.

Here, the level shift circuit in FIG. 3A carries out a level shift operation when the enable signal ENA is at the L level. In addition, in FIG. 3A, 413 is the source of the polysilicon thin film transistor 411.

As shown in FIG. 3B, it is clear in the present embodiment that the voltage at the node B when the polysilicon thin film transistor 417 which forms the switching element 217 for cutting off the current path is turned on (that is to say, during the period when the enable signal ENA in pulse waveform shown in FIG. 3B is at the L level) and the voltage at the node B when a direct current voltage (L level is continuously inputted into the gate 418 of the polysilicon thin film transistor 417 are the same.

Thus, when the level shift circuit in the present embodiment is used, the operation can be prevented from being affected by the properties of the polysilicon thin film transistor when the current path is cut off, and therefore, stable operation of the level shift circuit is possible.

Here, in the level shift circuit shown in FIG. 3A, the polysilicon thin film transistor 417 is turned off during the period when the enable signal ENA is at the H level, and the node B becomes of a floating state, and the polysilicon thin film transistor 411 is turned on in this state, and therefore, the voltage at the node B is low.

The gist of the present invention is that a switching element 217 for cutting off a current path is provided between the drain of the polysilicon thin film transistor for amplifying the voltage and the power source in gate grounded type voltage amplifying circuits.

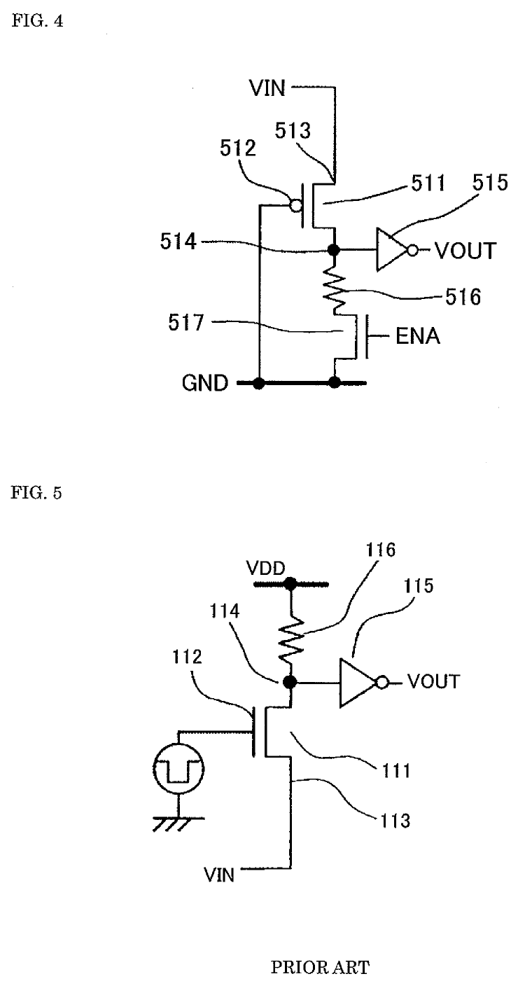

Accordingly, as shown in FIG. 4, in the case where a p type polysilicon thin film transistor 511 is used as a polysilicon thin film transistor for amplifying the voltage, an n type polysilicon thin film transistor 517 is provided between the drain 514 of the polysilicon thin film transistor 511 and the power source GND as the switching element 217 for cutting off the current path.

Here, in FIG. 4, 512 is the gate of the polysilicon thin film transistor 511, 513 is the source of the polysilicon thin film transistor 511, 515 is the inverter forming a waveform rectifying circuit, and 516 is a resistor In addition, in the level shift circuit shown in FIG. 4, an input signal (VIN) of which the L level is 3 V and the H level is 6 V is converted to a signal of which the L level is 0 V and the H level is 6 V.

Though in the above described embodiment, the present invention is applied to a liquid crystal display device, the present invention is not limited to this, and can, of course, be applied to level shift circuits used in other display devices, such as EL display devices, for example.

Though the invention made by the present inventor is described concretely on the basis of the above described embodiment, the present invention is not limited to the above described embodiment, and various modifications are, of course possible, provided that they remain in such a scope as not to deviate from the gist of the present invention.

What is claimed is:

1. A display device provided with a level shift circuit, characterized in that said level shift circuit comprises:
a first thin film transistor having a semiconductor layer formed of a polysilicon layer;
a waveform rectifying circuit connected to a second electrode of said first thin film transistor; and
a constant current source and a switching element connected between the second electrode of said first thin film transistor and a reference power source, wherein
a bias voltage is inputted into a control electrode of said first thin film transistor and an input signal is inputted into a first electrode of said first thin film transistor,
said first thin film transistor is an n type thin film transistor,
said input signal is a signal of which the voltage level changes between a second voltage and a third voltage of which the potential is higher than that of said second voltage,
the voltage level of said reference power source is a first voltage of which the potential is higher than that of said third voltage, and
said level shift circuit converts said input signal of which the voltage level changes between said third voltage and said second voltage to a signal of which the voltage level changes between said first voltage and said second voltage.

2. A display device provided with a level shift circuit, characterized in that
said level shift circuit comprises:
a first thin film transistor having a semiconductor layer formed of a polysilicon layer;
a waveform rectifying circuit connected to a second electrode of said first thin film transistor; and
a constant current source and a switching element connected between the second electrode of said first thin film transistor and a reference power source, wherein
a bias voltage is inputted into a control electrode of said first thin film transistor and an input signal is inputted into a first electrode of said first thin film transistor,
said first thin film transistor is a p type thin film transistor,
said input signal is a signal of which the voltage level changes between a fourth voltage and a fifth voltage of which the potential is lower than that of said fourth voltage,
the voltage level of said reference power source is a sixth voltage of which the potential is lower than that of said fifth voltage, and
said level shift circuit converts said input signal of which the voltage level changes between said fourth voltage and said fifth voltage to a signal of which the voltage level changes between said fourth voltage and said sixth voltage.

3. The display device according to claim 1, characterized in that said constant current source is a resistor.

4. The display device according to claim 1, characterized in that said switching element is formed of a second thin film transistor having a semiconductor layer formed of a polysilicon layer.

5 The display device according to claim 1, characterized in that
said switching element is formed of a second thin film transistor having a semiconductor layer formed of a polysilicon layer, and
said second thin film transistor also functions as said constant current source when in an on state.

6. The display device according to claim 2, characterized in that said constant current source is a resistor.

7. The display device according to claim 2, characterized in that said switching element is formed of a second thin film transistor having a semiconductor layer formed of a polysilicon layer.

8. The display device according to claim 2, characterized in that said switching element is formed of a second thin film transistor having a semiconductor layer formed of a polysilicon layer, and said second thin film transistor also functions as said constant current source when in an on state.
